(19) United States
(12) Patent Application Publication
(10) Pub. No.: US 2026/0106469 A1
(43) Pub. Date: Apr. 16, 2026

(54) CHARGING AND DISCHARGING SYSTEM

(71) Applicant: SAMSUNG SDI CO., LTD., Yongin-si (KR)

(72) Inventors: Sangheon HAN, Yongin-si (KR); Sejin PARK, Yongin-si (KR); Hyungu HEO, Yongin-si (KR); Kyoungheon HEO, Yongin-si (KR)

(21) Appl. No.: 19/346,776

(22) Filed: Oct. 1, 2025

(30) Foreign Application Priority Data
Oct. 15, 2024 (KR) 10-2024-0140648

(51) Int. Cl. H02J 7/00; H01M 10/613; H01M 10/6563; H05K 7/20

(52) U.S. Cl. CPC H02J 7/54; H01M 10/613; H01M 10/6563; H02J 7/663; H02J 7/70; H02J 7/80; H02J 7/96; H05K 7/20909

(57) ABSTRACT

The present disclosure provides a charging and discharging system. The system includes a power device, a tray configured to contain a first battery group comprising a first set of batteries connected in series and a second battery group comprising a second set of batteries connected in series. The system also includes a charging and discharging control board electrically connected to the power device, the first battery group, and the second battery group. The charging and discharging control board includes a first bypass relay providing a first path for making a series connection between the first battery group and the power device and a second path for releasing the series connection between the first battery group and the power device. The system further includes a second bypass relay providing a third path for making a series connection between the second battery group and the power device and a fourth path for releasing the series connection between the second battery group and the power device.

This application claims priority under 35 U.S.C §119 to Korean Patent Application No. 10-2024-0140648, filed in the Korean Intellectual Property Office on October 15, 2024, the entire contents of which are hereby incorporated by reference.

### BACKGROUND

### FIELD

Embodiments of the present disclosure relate to a charging and discharging system.

### DESCRIPTION OF THE RELATED ART

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

Series-type secondary battery chargers/dischargers have the advantage of supplying the same current between cells by connecting multiple cells in series. However, there may be a problem in series-type secondary battery chargers/dischargers in that if an error occurs in one cell, the error can affect all the cells. In particular, there may arise a problem of having to reconfigure the entire system as part of a process of replacing or repairing the erroneous cell.

The above information disclosed in this Background section is for enhancement of understanding of the background of the present disclosure, and therefore, it may contain information that does not constitute related (or prior) art.

### SUMMARY

Embodiments of the present disclosure provide a charging and discharging system to solve the above-described problems, though the present disclosure is not limited to solving the above-described problems.

These and other aspects and features of the present disclosure will be described in or will be apparent from the following description of embodiments of the present disclosure.

In order to solve the technical problem, a charging and discharging system according to one or more embodiments of the present disclosure includes a power device, a tray configured to contain a first battery group including a first set of batteries connected in series and a second battery group including a second set of batteries connected in series, and a charging and discharging control board electrically connected to the power device, the first battery group, and the second battery group, and the charging and discharging control board includes a first bypass relay providing a first path for making a series connection between the first battery group and the power device and a second path for releasing the series connection between the first battery group and the power device, and a second bypass relay providing a third path for making a series connection between the second battery group and the power device and a fourth path for releasing the series connection between the second battery group and the power device.

According to one or more embodiments, the charging and discharging system may further include a control unit configured to control the charging and discharging control board, and the control unit may be configured to stop a charging and discharging job for the first battery group by controlling the first bypass relay to provide the second path.

According to one or more embodiments, the charging and discharging system may further include a first probe electrically connecting a first end of the first battery group and a first terminal of the first bypass relay, a second probe electrically connecting a second end of the first battery group and a second terminal of the first bypass relay, a third probe electrically connecting a first end of the second battery group and a first terminal of the second bypass relay, and a fourth probe electrically connecting a second end of the second battery group and a second terminal of the second bypass relay, and when the first bypass relay provides the first path, the second terminal of the first bypass relay and a third terminal of the first bypass relay may be electrically connected, and the third terminal of the first bypass relay may be electrically connected to the third probe.

According to one or more embodiments, when the first bypass relay provides the second path, the first terminal of the first bypass relay and the third terminal of the first bypass relay may be electrically connected.

According to one or more embodiments, the charging and discharging system may further include a plurality of additional probes connecting the first set of batteries in the first battery group in series.

According to one or more embodiments, the charging and discharging system may further include a connection structure fixing a first additional probe and a second additional probe of the plurality of additional probes, and the first additional probe and the second additional probe may be electrically connected to each other.

According to one or more embodiments, the connection structure may be configured to make a distance between the first additional probe and the second additional probe to be greater than or equal to a predetermined minimum distance and less than or equal to a predetermined maximum distance.

According to one or more embodiments, the connection structure may be a sliding rail.

According to one or more embodiments, the first probe may be configured to connect to a positive terminal of the first battery, the first additional probe is configured to be connected to a negative terminal of the first battery, the second additional probe is configured to be connected to a positive terminal of a second battery, and the first additional probe and the second additional probe are configured to connect the first battery and the second battery in series.

According to one or more embodiments, the charging and discharging system may further include a plurality of positive probes configured to be connected to positive terminals of the first battery group, a plurality of negative probes configured to be connected to negative terminals of the first battery group, a first driving unit configured to move the plurality of positive probes in a horizontal direction, and a second driving unit configured to move the plurality of negative probes in a horizontal direction.

According to one or more embodiments, the charging and discharging system may further include a control unit configured to receive information associated with the first set of batteries included in the first battery group and configured to control at least one of the first driving unit or the second driving unit based on the received information.

According to one or more embodiments, the information associated with the first set of batteries may include information on a distance between a positive terminal and a negative terminal of a battery.

According to one or more embodiments, the charging and discharging control board may further include a third bypass relay providing a fifth path for making a series connection between a third battery group and the power device and a sixth path for releasing the series connection between the third battery group and the power device, the charging and discharging system may further include a fifth probe configured to electrically connect one end of the third battery group and a first terminal of the third bypass relay and a sixth probe configured to electrically connect the other end of the third battery group and a second terminal of the third bypass relay, a positive terminal of the power device may be electrically connected to the first probe via a first power cable, and a negative terminal of the power device may be connected to a third terminal of the third bypass relay via a second power cable.

According to one or more embodiments, the charging and discharging system may further include a lifting plate with the tray being disposed on an upper surface of the lifting plate, a lifting device configured to lift the lifting plate, and a control unit configured to control the lifting device, and the charging and discharging system is configured such that when the tray may be raised by the lifting device (i) the first probe and the second probe to contact the first battery group and (ii) the third probe and the fourth probe contact the second battery group.

According to one or more embodiments, the charging and discharging system may further include a lower stopper disposed on the lifting plate, and an upper stopper opposing the lower stopper, and the control unit may be configured to control the lifting device to raise the lifting plate until the upper stopper and the lower stopper come into contact.

According to one or more embodiments, the control unit is configured to select the lower stopper out of a plurality of lower stoppers based on information associated with the first set of batteries included in the first battery group.

According to one or more embodiments, the charging and discharging system may further include a tray alignment device configured to control a position of the tray in a horizontal direction, and the control unit may be configured to control the lifting device so that the lifting plate is raised to a predetermined height, and the control unit may be configured to control the tray alignment device so that the position of the tray in the horizontal direction is aligned at the predetermined height.

According to one or more embodiments, the charging and discharging system may further include a power cooling device configured to cool the power device, and a battery cooling device configured to cool the first set of batteries and the second set of batteries.

A charging and discharging system according to one or more embodiments of the present invention includes a power device, a bypass relay configured to provide a first path that makes a series connection between a battery group and the power device and a second path that releases the series connection between the battery group and the power device, a first probe configured to electrically connect a first end of the battery group and a first terminal of the bypass relay, a second probe configured to electrically connect a second end of the battery group and a second terminal of the bypass relay, and a plurality of additional probes connecting batteries in the battery group in series, wherein when the bypass relay provides the first path, the second terminal of the bypass relay and a third terminal of the bypass relay are electrically connected, and when the bypass relay provides the second path, the first terminal of the bypass relay and the third terminal of the bypass relay are electrically connected.

According to one or more embodiments, a positive terminal of the power device may be electrically connected to the first probe via a first power cable, and the third terminal of the bypass relay may be electrically connected to a subsequent probe that is configured to be associated with a subsequent battery group.

According to various embodiments of the present disclosure, the charging and discharging system can improve the overall efficiency of the charging and discharging system and prevent battery performance degradation, damage, or the like due to overcharging by selectively controlling the series connection between a particular battery group of the plurality of battery groups and the power device. Specifically, the charging and discharging system may be configured to cut off the current flowing to a battery (or battery group) whenever the battery (or battery group) reaches a target voltage and cut off when the last battery (or battery group) that has not reached the target voltage reaches the target voltage, while charging and discharging batteries connected in series in a constant current mode.

According to various embodiments of the present disclosure, the power cables are connected only to the first probe and the last probe regardless of the number of batteries connected in series, which can significantly reduce costs.

According to various embodiments of the present disclosure, the charging and discharging system can perform a job of charging and discharging all the batteries in series by electrically connecting a plurality of battery groups, each of which includes batteries connected in series, to each other in series using the bypass relays.

However, aspects and features of the present disclosure are not limited to those described above, and other aspects and features not mentioned will be clearly understood by a person skilled in the art from the detailed description, described below.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 is a block diagram showing the configuration of a charging and discharging system according to an embodiment of the present disclosure;

FIG. 2 is a block diagram showing the configuration of a charging and discharging system according to an embodiment of the present disclosure;

FIG. 3 is a block diagram showing the configuration of a charging and discharging system according to one embodiment of the present disclosure;

FIG. 4 is a configuration diagram showing an example of a charging and discharging system according to an embodiment of the present disclosure;

FIG. 5 shows an example of a first path and a second path provided by a bypass relay according to an embodiment of the present disclosure;

FIG. 6 is a configuration diagram showing the operation of a charging and discharging system according to an embodiment of the present disclosure;

FIG. 7 is a configuration diagram showing the operation of a charging and discharging system according to an embodiment of the present disclosure;

FIG. 8 is a configuration diagram showing a charging and discharging system according to an embodiment of the present disclosure;

FIG. 9 is a side view of a charging and discharging system according to an embodiment of the present disclosure;

FIG. 10 is a diagram showing the structure of a charging and discharging system according to an embodiment of the present disclosure;

FIG. 11 is a diagram showing the structure of a charging and discharging system according to an embodiment of the present disclosure;

FIG. 12 is a diagram showing the configuration of a charging and discharging system according to an embodiment of the present disclosure; and

FIG. 13 is a diagram showing a control unit of a charging and discharging system according to an embodiment of the present disclosure.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being "coupled" or "connected" to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of "may" when describing embodiments of the present disclosure relates to "one or more embodiments of the present disclosure." Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms "substantially," "about," and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or "over" the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms "includes," "including," “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of "1.0 to 10.0" is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being "linked," "coupled," or "connected" to another component, the elements may be directly “coupled,” “linked” or "connected" to each other, or another component may be "interposed" between the components".

Throughout the specification, when "A and/or B" is stated, it means A, B or A and B, unless otherwise stated. That is, “and/or” includes any or all combinations of a plurality of items enumerated. When "C to D" is stated, it means C or more and D or less, unless otherwise specified.

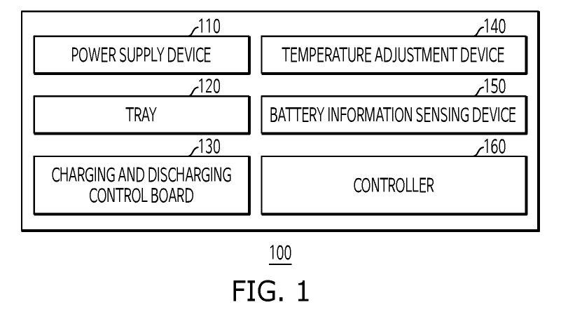

FIGS. 1 to 3 are block diagrams showing the configuration of a charging and discharging system 100 according to an embodiment of the present disclosure. The charging and discharging system 100 may include a power supply unit 110, a tray 120, a charging and discharging control board 130, a temperature adjustment unit 140, a battery information sensing unit 150, and a control unit 160.

The power supply unit 110 may supply voltage and current in the charging and discharging process of a battery (e.g., a secondary battery). Specifically, the power supply unit 110 may supply power to the battery during charging, and the power supply unit 110 may supply power to an external circuit from the battery during discharging. For example, the power supply unit 110 may supply a constant current or a constant voltage.

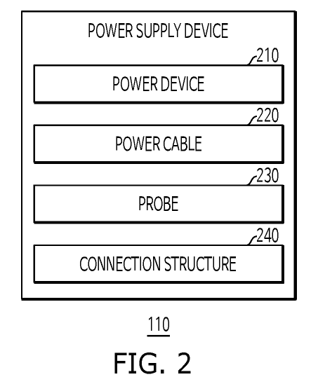

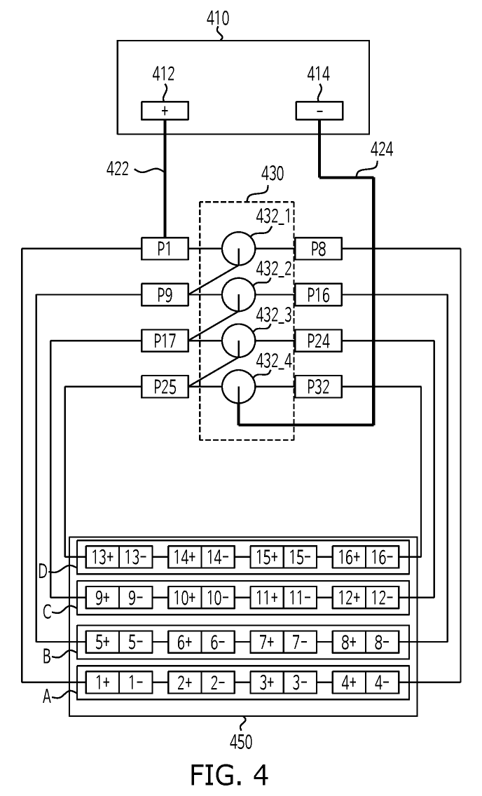

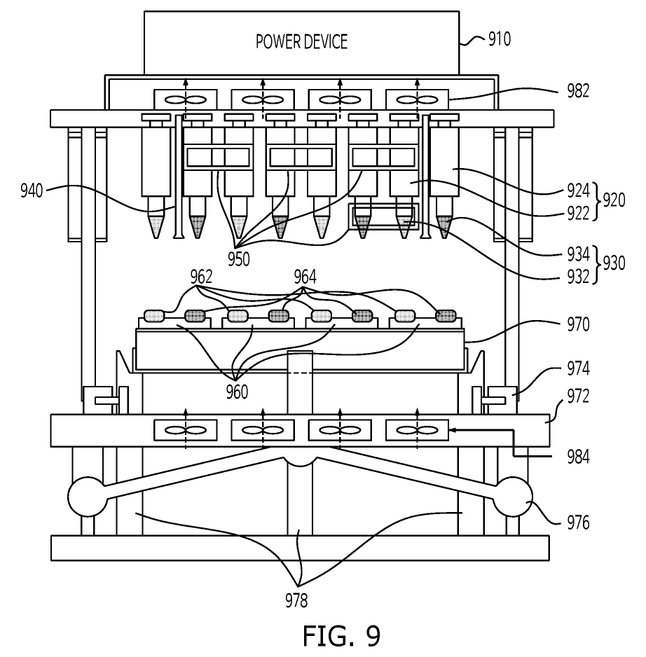

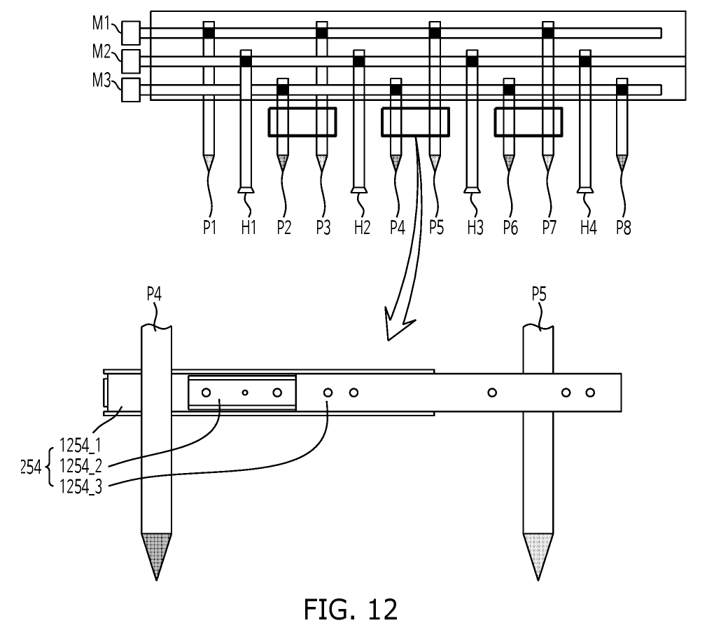

Referring to FIG. 2, the power supply unit 110 may include a power device 210, a power cable 220, a probe 230, and a connection structure 240. The power device 210 may be electrically connected to a battery to be charged and discharged via the power cable 220 and the probe 230. Descriptions of these structures will be given below in relation to FIG. 4 and subsequent figures. The probe 230 may be electrically connected to a corresponding battery by contacting each electrode terminal of the battery. In one example, the probe 230 may include a probe tip that functions to electrically connect to each electrode terminal of the battery and a probe fixture that physically supports the probe. A description of the probe 230 will be given below in relation to FIG. 9 and subsequent figures. For the convenience of managing the probe 230, two probes connecting two batteries in series can be physically coupled to each other via the connection structure 240. A description of the connection structure 240 will be given below in relation to FIG. 12.

Referring again to FIG. 1, the tray 120 may be configured to house batteries to be charged and discharged. Here, the tray 120 may house a first battery group including a first set of batteries connected in series. The tray 120 may further house a second battery group including a second set of batteries connected in series. Here, the numbers of batteries in each of the first and second sets included in the first and second battery groups may be the same or different from each other. Further, the tray 120 may house any number of battery groups.

The tray 120 may be placed on a tray support included in the charging and discharging system, and the tray 120 may be raised together with the tray support by a lifting device. A charging and discharging job may be performed on the batteries housed in the raised tray 120 by the power supply unit 110. A detailed description of such charging and discharging will be given below in relation to FIG. 9 and subsequent figures.

The charging and discharging control board 130 may connect in series the battery groups to perform a charging and discharging job for the battery groups disposed on the tray 120. To this end, the charging and discharging control board 130 may include a bypass relay that provides a first path for making a series connection between a particular battery group and the power device 210 and a second path for releasing the series connection between the particular battery group and the power device 210. The charging and discharging control board 130 may be connected to the power device 210 via the power cable 220. Further, the charging and discharging control board 130 may be connected to the probe 230.

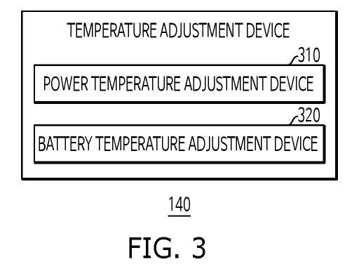

The temperature adjustment unit 140 may adjust the temperature of devices associated with the charging and discharging system 100. Referring to FIG. 3, the temperature adjustment unit 140 may include a power temperature adjustment unit 310 and a battery temperature adjustment unit 320. In an example, the temperature adjustment unit 140 may include at least one cooling fan.

In an embodiment, the power temperature adjustment unit 310 may include a power cooling device configured to cool the power device 210. However, the present disclosure is not limited to such a configuration. For example, the power temperature adjustment unit 310 may perform preheating to allow the power device 210 to perform a charging and discharging job.

The battery temperature adjustment unit 320 may include a battery cooling device configured to cool a battery that is a target for a charging and discharging job performed by the charging and discharging system 100. However, the present disclosure is not limited thereto. For example, the battery temperature adjustment unit 320 may in alternative or in addition perform preheating of the battery for a charging and discharging job.

Referring again to FIG. 1, the battery information sensing unit 150 may sense information associated with the battery to be charged and discharged. Here, the information associated with the battery may include battery specifications, type, charging and discharging state, temperature, a structure in which a plurality of batteries including the battery are electrically connected, etc. However, the present disclosure is not limited to a battery information sensing unit 150 configured to sense such information. For example, the battery information sensing unit 150 may include height information of the tray on which the batteries are disposed, location information of the batteries on the tray, information on whether the probe and the terminals of the batteries are in contact, temperature information of the power device, etc.

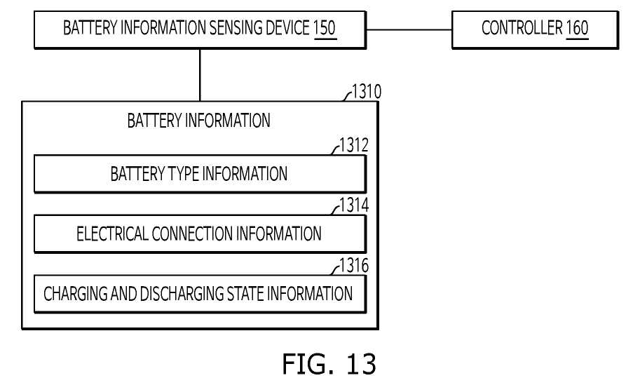

The control unit 160 may control a series of processes in which the charging and discharging system 100 performs a charging and discharging job of the batteries. Here, the processes may include a job of structurally modifying the charging and discharging system or electrically modifying the charging and discharging method of the battery, etc., based on the information associated with the battery. The control unit 160 may control the charging and discharging job of the charging and discharging system 100 by exchanging information (or data) with other components of the charging and discharging system 100, which will be described below in relation to FIG. 13. Further, the control unit 160 may control the charging and discharging job of the charging and discharging system 100 by receiving information associated with the battery sensed by the battery information sensing unit 150. A description of such control will be given below in relation to FIG. 13.

The control unit 160 may control the electrical connection structure of the plurality of battery groups by controlling the charging and discharging control board 130. For example, the control unit 160 may perform the charging and discharging job by controlling the bypass relay to provide the first path for making a series connection between a particular battery group and the power device 210 by controlling the charging and discharging control board 130. Further, the control unit 160 may stop the charging and discharging job by controlling the bypass relay to provide the second path for releasing the series connection between the particular battery group and the power device 210 by controlling the charging and discharging control board 130. A detailed description of such operations follows.

FIG. 4 is a configuration diagram showing an example of a charging and discharging system according to an embodiment of the present disclosure. The charging and discharging system may include a power device 410, power cables 422 and 424, a charging and discharging control board 430, a probe P, and a tray 450.

The tray 450 may be configured to house battery groups including batteries connected in series. FIG. 4 shows that the tray 450 is configured to house four battery groups, including a first battery group A including a first set of batteries connected in series, a second battery group B including a second set of batteries connected in series, a third battery group C including a third set of batteries connected in series, and a fourth battery group D including a fourth set of batteries connected in series. However, FIG. 4 is merely an example of one possible arrangement of a tray 450 according to the present disclosure, and the present disclosure includes various other arrangements and configurations. For example, the tray 450 may be configured to house one or more battery groups.

Each battery group may include batteries connected in series. FIG. 4 shows that each of the first to fourth battery groups A to D includes four batteries, with the batteries in each group A to D being connected in series. However, this arrangement is merely one example and the present disclosure is not limited thereto. In various examples, one or more of the battery groups may include one battery, and in other examples, each of the battery groups may include more than one battery connected in series. Further, the numbers of batteries included in each of the battery groups may be the same or different from each other.

Each of the batteries in the battery groups may include a positive terminal and a negative terminal. For example, the first set of batteries in the first battery group A may include a first battery, a second battery, a third battery, and a fourth battery. Here, the first battery may include a positive terminal 1+ and a negative terminal 1-. Further, the second battery may include a positive terminal 2+ and a negative terminal 2-. In other words, the n-th battery may include a positive terminal n+ and a negative terminal n-.

The charging and discharging control board 430 may be electrically connected to the battery groups A to D. Here, the charging and discharging control board 430 may include bypass relays 432_1 to 432_4 that provide paths for making series connections between the battery groups A to D and the power device 410 and paths for releasing the series connections between the battery groups and the power device 410. The charging and discharging control board 430 may connect some or all of the four battery groups A to D in series with the power device 410 by controlling the bypass relays 432_1 to 432_4. Descriptions of each path provided by the bypass relays and a charging and discharging job of the charging and discharging system based thereon will be described below.

In the example shown, the charging and discharging control board 430 may include a first bypass relay 432_1, a second bypass relay 432_2, a third bypass relay 432_3, and a fourth bypass relay 432_4. However, the present disclosure is not limited to a configured with four bypass relays. For example, the charging and discharging control board 430 may include one relay, or, in other examples, the charging and discharging control board 430 may include two or more bypass relays. Here, the number of bypass relays included in the charging and discharging control board 430 may correspond to the number of battery groups.

The probe P may electrically connect the battery groups A to D, the charging and discharging control board 430, and the power device 410. The probe P may electrically connect the battery and the power device by contacting the electrode terminals of the battery included in the battery group.

In the example shown in FIG. 4, a first probe P1 may electrically connect one end 1+ of the first battery group A and a first terminal of the first bypass relay 432_1. Further, a second probe P8 may electrically connect the other end 4- of the first battery group A and a second terminal of the first bypass relay 432_1. Moreover, a third probe P9 may electrically connect one end 5+ of the second battery group B, a first terminal of the second bypass relay 432_2, and a third terminal of the first bypass relay 432_1. And a fourth probe P16 may electrically connect the other end 8- of the second battery group B and a second terminal of the second bypass relay 432_2.

Still referring to FIG. 4, a fifth probe P17 may electrically connect one end 9+ of the third battery group C, a first terminal of the third bypass relay 432_3, and a third terminal of the second bypass relay 432_2. Moreover, a sixth probe P24 may electrically connect the other end 12- of the third battery group C and a second terminal of the third bypass relay 432_3. Further, a seventh probe P25 may electrically connect one end 13+ of the fourth battery group D, a first terminal of the fourth bypass relay 432_4, and a third terminal of the third bypass relay 432_3. And an eighth probe P32 may electrically connect the other end 16- of the fourth battery group D and a second terminal of the fourth bypass relay 432_4.

The battery groups A to D may be electrically connected to one or more of a subsequent battery group via one of the bypass relays 432 and the probes P. With this configuration, at least some of the plurality of battery groups A to D may be electrically connected in series with the power device 410 described later. For example, the third terminal of the first bypass relay 432_1 associated with the first battery group A may be electrically connected to the third probe P9 associated with the second battery group B corresponding to the subsequent battery group of the first battery group A. Further, the third terminal of the second bypass relay 432_2 associated with the second battery group B may be electrically connected to the fifth probe P17 associated with the third battery group C corresponding to the subsequent battery group of the second battery group B. Likewise, the third terminal of the third bypass relay 432_3 associated with the third battery group C may be electrically connected to the seventh probe P25 associated with the fourth battery group D corresponding to the subsequent battery group of the third battery group C.

The power device 410 may be electrically connected to the probe P and/or the bypass relay via the power cables 422 and 424. In the depicted example, the positive terminal 412 of the power device 410 may be electrically connected to the first probe P1 via the first power cable 422. As the first probe P1 can electrically connect one end 1+ of the first battery group A and the first terminal of the first bypass relay 432_1, the first battery group A can be electrically connected to the positive terminal 412 of the power device 410.

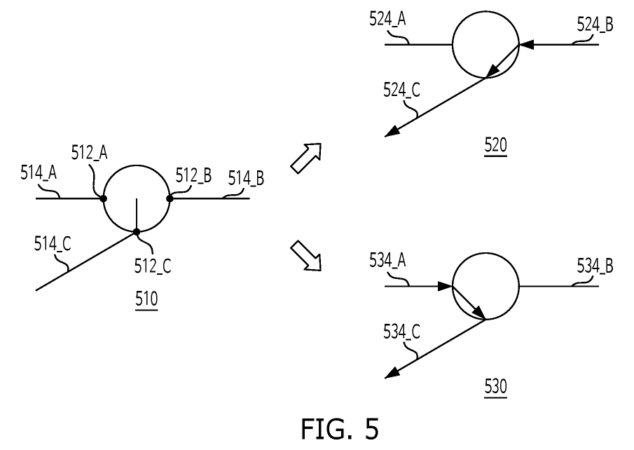

The negative terminal 414 of the power device 410 may be electrically connected to the third terminal of the fourth bypass relay 432_4 via the second power cable 424. in which the second terminal and the third terminal of the fourth bypass relay 432_4 are electrically connected (see 520 in FIG. 5), the eighth probe P32 may electrically connect the other end 16- of the fourth battery group D and the second terminal of the fourth bypass relay 432_4. Thus, the fourth battery group D may be electrically connected to the negative terminal 414 of the power device 410.

Each set of batteries included in the battery groups A to D may be connected in series. The charging and discharging system may include additional probes (not shown) that connect the batteries in each battery group A to D in series. In the depicted example, the first set of batteries in the first battery group A may include a first battery and a second battery. The first probe P1 may be connected to the positive terminal 1+ of the first battery. Further, the negative terminal 1- of the first battery may be connected to a first additional probe, and the positive terminal 2+ of the second battery may be connected to a second additional probe. Here, the first additional probe and the second additional probe may be electrically connected to each other via a connection cable or the like. Accordingly, the first battery and the second battery may be electrically connected in series via the first and second additional probes. In this way, the batteries included in each battery group A to D may be connected in series with each other.

The additional probes may include a negative additional probe connected to the negative terminal of the battery and a positive additional probe connected to the positive terminal of the battery. The negative additional probe and the positive additional probe that are consecutive to each other may be connected to each other via a probe connection cable.

The power cables 422 and 424 may be thicker and more expensive as compared to the probe connection cables. Therefore, connecting the positive terminal 412 and negative terminal 414 of the power device 410 to each of the positive and negative terminals of each of the plurality of batteries via the power cables 422 and 424 may be expensive. For example, if 16 batteries are connected to the power device 410 using the power cables 422 and 424, then 32 power cables 422 and 424 may be needed. In contrast, if 16 batteries are connected in series via the charging and discharging control board 430, the probes (including the additional probes), and the probe connection cables as depicted in FIG. 4, then the batteries 16 can be connected in series with the power device 410 using only two power cables 422 and 424. With the depicted configuration, the power cables 422 and 424 are connected only to the first probe and the last probe regardless of the number of batteries connected in series (e.g., 16), which can significantly reduce costs.

FIG. 5 is a diagram showing an example of a first path and a second path provided by a bypass relay according to an embodiment of the present disclosure. The bypass relay may provide a first path for making a series connection between the battery group and the power device, or a second path for releasing the series connection between the battery group and the power device. In an example, the control unit may control the bypass relay to provide the first path or the second path by controlling the charging and discharging control board. As shown, the bypass relay may include terminals 512 and conductors 514 electrically connected to each terminal.

A first state 510 may represent a state in which the bypass relay is electrically isolated without selecting either the first path or the second path. As a first terminal 512_A included in the bypass relay in the first state 510 is in an open state, no current can flow along a first conductor 514_A. Further, as a second terminal 512_B and a third terminal 512_C included in the bypass relay in the first state 510 are also in open states, no current can flow along a second conductor 514_B and a third conductor 514_C. That is, the third terminal 512_C may not be electrically connected to the first terminal 512_A and the second terminal 512_B in the first state 510.

Each of the bypass relays 432 included in the charging and discharging control board 430 of FIG. 4 may be in open states in the same manner as the bypass relay in the first state 510 of FIG. 5. Accordingly, the battery groups A to D and the power device 410 in FIG. 4 may be in an electrically isolated state.

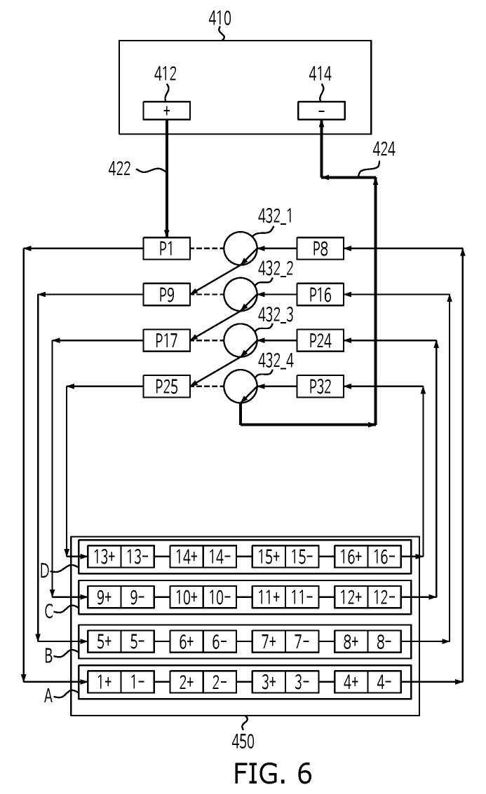

A second state 520 is a state in which the bypass relay provides the first path. In an embodiment, the second terminal 512_B and the third terminal 512_C of the bypass relay may be electrically connected. Accordingly, a second conductor 524_B connected to the second terminal 512_B and a third conductor 524_C connected to the third terminal 512_C may be electrically connected. And because the first terminal 512_A is open, a first conductor 524_A connected to the first terminal 512_A may be insulated. Accordingly, the bypass relay in the second state 520 can provide the first path in which the battery groups and the power device are connected in series. A description regarding how the charging and discharging system utilizes the bypass relay in the second state 520 will be given below in relation to FIG. 6.

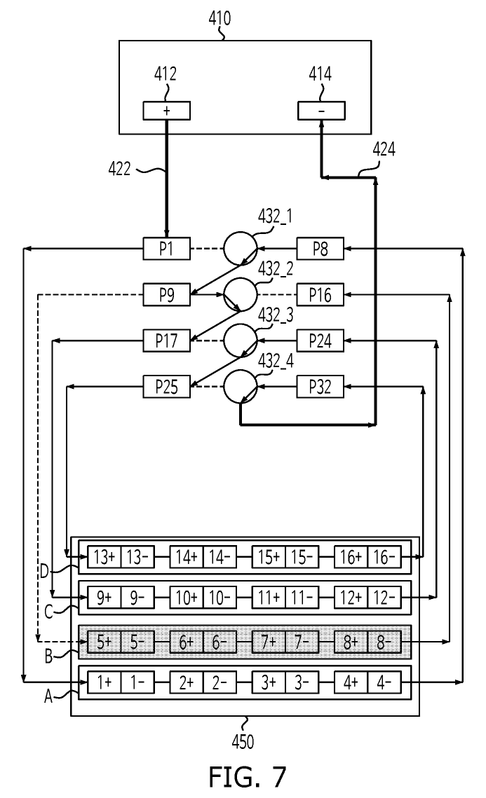

A third state 530 is a state in which the bypass relay provides the second path. In this state, the first terminal 512_A and the third terminal 512_C of the bypass relay may be electrically connected. Accordingly, a first conductor 534_A connected to the first terminal 512_A and a third conductor 534_C connected to the third terminal 512_C may be electrically connected. And because the second terminal 512_B is open, the second conductor 534_B connected to the second terminal 512_B may be insulated. The bypass relay in the third state 530 may provide the second path in which the series connection between the battery groups and the power device is released. A description regarding how the charging and discharging system utilizes the bypass relay in the third state 530 will be given below in relation to FIG. 7.

FIG. 6 is a configuration diagram showing the operation of a charging and discharging system according to an embodiment of the present disclosure. In particular, FIG. 6 shows an example of utilizing the bypass relay in the second state 520 described in FIG. 5.

Referring to FIG. 6, the positive terminal 412 of the power device 410 may be electrically connected to the first probe P1 via the first power cable 422. Further, the first probe P1 may electrically connect one end of the first battery group A including the first set of batteries connected in series and the first terminal of the first bypass relay 432_1. Here, the first probe P1 may be electrically connected to the first battery by physically contacting the positive terminal 1+ of the first battery included in the first battery group A.

The first set of batteries included in the first battery group A may be electrically connected in series with each other via additional probes (not shown) and probe connection cables (not shown). For example, a first additional probe may physically contact the negative terminal 1- of the first battery, and a second additional probe may physically contact the positive terminal 2+ of the second battery. And the first additional probe and the second additional probe may be electrically connected via a probe connection cable.

The second probe P8 may electrically connect the other end of the first battery group A including the first set of batteries connected in series and the second terminal of the first bypass relay 432_1. Here, the second probe P8 may be electrically connected to the fourth battery by physically contacting the negative terminal 4- of the fourth battery included in the first battery group A.

Referring to FIGS. 5 and 6, the first bypass relay 432_1 in the second state 520 may provide the first path in which the first battery group A and the power device 410 are connected in series. In this state, the second terminal and third terminal of the first bypass relay 432_1 may be electrically connected to each other. Accordingly, the conductor connected to the second terminal of the first bypass relay 432_1 and the conductor connected to the third terminal may be electrically connected to each other.

The third terminal of the first bypass relay 432_1 associated with the first battery group A may be electrically connected to the third probe P9 associated with the second battery group B that is a subsequent battery group of the first battery group A. Accordingly, the third probe P9 may be connected in series with the positive terminal 412 of the power device 410.

Similarly, the third probe P9 may electrically connect one end 5+ of the second battery group B including the second set of batteries connected in series and the first terminal of the second bypass relay 432_2. Further, the second set of batteries included in the second battery group B may be electrically connected in series with each other via additional probes and probe connection cables. Moreover, the fourth probe P16 may electrically connect the other end 8- of the second battery group B including the second set of batteries connected in series and the second terminal of the second bypass relay 432_2. Referring to FIGS. 5 and 6, the second bypass relay 432_2 in the second state 520 may provide the first path in which the second battery group B and the power device 410 are connected in series.

The fifth probe P17 may electrically connect one end 9+ of the third battery group C including the third set of batteries connected in series and the first terminal of the third bypass relay 432_3. Further, the third set of batteries included in the third battery group C may be electrically connected in series with each other via additional probes and probe connection cables. Moreover, the sixth probe P24 may electrically connect the other end 12- of the third battery group C including the third set of batteries connected in series and the second terminal of the third bypass relay 432_3. Referring to FIGS. 5 and 6, the third bypass relay 432_3 in the second state 520 may provide the first path in which the third battery group C and the power device 410 are connected in series.

The seventh probe P25 may electrically connect one end 13+ of the fourth battery group D including the fourth set of batteries connected in series and the first terminal of the fourth bypass relay 432_4. Further, the fourth set of batteries included in the fourth battery group D may be electrically connected in series with each other via additional probes and probe connection cables. Moreover, the eighth probe P32 may electrically connect the other end 16- of the fourth battery group D including the fourth set of batteries connected in series and the second terminal of the fourth bypass relay 432_4. Referring to FIGS. 5 and 6, the fourth bypass relay 432_4 in the second state 520 may provide the first path in which the fourth battery group D and the power device 410 are connected in series.

Through the configuration depicted in FIG. 6 and described above, the charging and discharging system can perform charging and discharging all the batteries in series by electrically connecting battery groups, each of which includes batteries connected in series, to each other in series using the bypass relays.

FIG. 7 is a configuration diagram showing the operation of a charging and discharging system according to an embodiment of the present disclosure. In particular, FIG. 7 shows an example of using the bypass relay in the third state 530 shown in FIG. 5.

Referring to FIG. 1, the battery information sensing unit 150 may sense aspects of each of the batteries included in the plurality of battery groups A to D such as whether the batteries are defective, have completed charging, etc. Further, the battery information sensing unit 150 may sense whether each of the battery groups A to D is defective, has completed charging, etc.

The example in FIG. 7 shows an example in which, when a particular battery group (or a particular battery included in the particular battery group) is determined to be defective or have completed charging, only the particular battery group (e.g., the second battery group B) is not subjected to a charging and discharging job. To this end, the control unit may control the second bypass relay 432_2 to release the series connection between the second battery group B and the power device 410 based on information received from the battery information sensing unit 150, etc.

In comparison with FIG. 6, the control unit may control the second bypass relay 432_2 to provide the second path in which the series connection between the second battery group B and the power device 410 is released. That is, the control unit closes the first path in which the second battery group B and the power device 410 are connected in series. Here, the electrical connection between the second terminal and third terminal of the second bypass relay 432_2 may be released, and the first terminal and the third terminal may be electrically connected to each other. Accordingly, the electrical connection between the conductor connected to the second terminal of the second bypass relay 432_2 and the conductor connected to the third terminal may be released, and the conductor connected to the first terminal and the conductor connected to the third terminal may be electrically connected. With this configuration, the control unit stops the charging and discharging job for the second battery group B.

As shown in FIG. 7, the bypass relays 432_1, 432_3, and 432_4 (i.e., other than the second bypass relay 432_2) provide the first path for making a series connection between the battery groups and the power device 410. Thus, the first battery group A, the third battery group C, and the fourth battery group D may be connected in series with the power device 410 and the charging and discharging job can be continuously performed.

With the above configuration, the efficiency of the charging and discharging system can be improved. Further, battery performance degradation, damage, or the like due to overcharging can be prevented by selectively controlling the series connection between a particular battery group of battery groups and the power device. Specifically, the charging and discharging system may be configured to cut off the current flowing to a battery (or battery group) whenever the battery (or battery group) reaches a target voltage and cut off the current when the last battery (or battery group) that has not reached the target voltage reaches the target voltage, while charging and discharging batteries connected in series in a constant current mode.

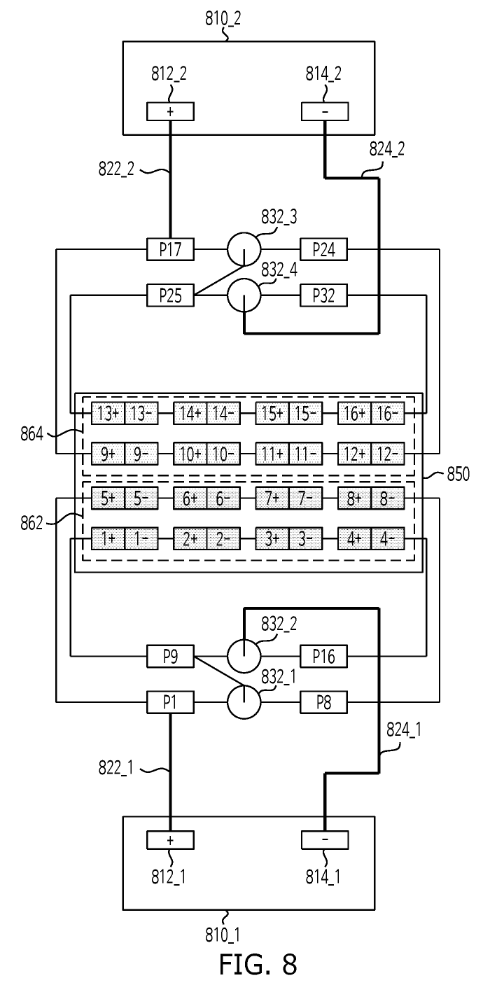

FIG. 8 is a configuration diagram showing a charging and discharging system according to an embodiment of the present disclosure. in this embodiment, a plurality of power devices 810_1 and 810_2 may perform a charging and discharging job by dividing a plurality of battery clusters 862 and 864.

A plurality of batteries (e.g., 16 batteries) may be divided into certain clusters, and a charging and discharging job may be performed by a power device for each of the clusters. For example, a first power device 810_1 may perform a charging and discharging job of a first battery cluster 862 including a first battery group (e.g., a group in which first to fourth batteries are connected in series) and a second battery group (e.g., a group in which fifth to eighth batteries are connected in series). Further, a second power device 810_2 may perform a charging and discharging job of a second battery cluster 864 including a third battery group (a group in which ninth to twelfth batteries are connected in series) and a fourth battery group (a group in which thirteenth to sixteenth batteries are connected in series).

The positive terminal 812_1 of the first power device 810_1 may be electrically connected to a first probe P1 via a first power cable 822_1 of the first power device. Further, the first probe P1 may electrically connect one end 1+ of the first battery group connected in series and the first terminal of a first bypass relay 832_1. A second probe P8 may electrically connect the other end 4- of the first battery group and the second terminal of the first bypass relay 832_1. Furthermore, the third terminal of the first bypass relay 832_1 may be electrically connected to a third probe P9.

Similarly, the third probe P9 may electrically connect one end 5+ of the second battery group connected in series and the first terminal of a second bypass relay 832_2. Further, a fourth probe P16 may electrically connect the other end 8- of the second battery group and the second terminal of the second bypass relay 832_2. The third terminal of the second bypass relay 832_2 may be electrically connected to the negative terminal 814_2 of the first power device 810_1 via a second power cable 824_1 of the first power device 810_1.

The positive terminal 812_2 of the second power device 810_2 may be electrically connected to a fifth probe P17 via a first power cable 822_2 of the second power device. Further, the fifth probe P17 may electrically connect one end 9+ of the third battery group connected in series and the first terminal of a third bypass relay 832_3. A sixth probe P24 may electrically connect the other end 12- of the third battery group and the second terminal of the third bypass relay 832_3. Further, the third terminal of the third bypass relay 832_3 may be electrically connected to a seventh probe P25.

Similarly, the seventh probe P25 may electrically connect one end 13+ of the fourth battery group connected in series and the first terminal of a fourth bypass relay 832_4. Further, an eighth probe P32 may electrically connect the other end 16- of the fourth battery group and the second terminal of the fourth bypass relay 832_4. The third terminal of the fourth bypass relay 832_4 may be electrically connected to the negative terminal 814_2 of the second power device 810_2 via a second power cable 824_2 of the second power device.

FIG. 9 is a side view of a charging and discharging system according to an embodiment of the present disclosure. The charging and discharging system may include a power device 910, probes 920 and 930, gas vent ports 940, connection structures 950, batteries 960, a tray 970, a tray lifting plate 972, a tray alignment device 974, a lifting device 976, a tray support 978, and temperature adjustment devices 982 and 984.

The power device 910 may correspond to the power device 210 of FIGS. 1 and 2. The power device 910 is shown as being disposed on the upper surface of the ceiling of the charging and discharging system in FIG. 9. But the present disclosure is not limited to such an arrangement.

The probes 920 and 930 of FIG. 9 may correspond to the probe 230 of FIGS. 1 and 2. Here, the probes 920 and 930 may be disposed on the underside of the ceiling of the charging and discharging system. The probes may include probe tips 930 that may be electrically connected to the respective electrode terminals 962 and 964 of the batteries 960 and probe fixtures 920 that physically support each of the probe tips 930. The probe tips 930 may include positive probe tips 932 that are electrically connected to the positive terminals 962 of the batteries 960 and negative probe tips 934 that are electrically connected to the negative terminals 964 of the batteries 960. The probe fixtures 920 may include positive probe fixtures 922 that support the positive probe tips 932 and negative probe fixtures 924 that support the negative probe tips 934. In an embodiment, the probes 920 and 930 may include a plurality of probes (e.g., the first probe of FIG. 4) electrically connected to the bypass relay and a plurality of additional probes (e.g., the additional probes of FIG. 4) connecting the batteries in the battery groups in series.

The connection structures 950 may fix a first additional probe and a second additional probe. The connection structures 950 may include connection structures that fix between adjacent probe fixtures and/or connection structures that fix between adjacent probe tips. The connection structures 950 make probe management easier by adjusting or limiting the distance between adjacent additional probes that are physically coupled to each other. Further, a plurality of probe structures can be adjusted using the connection structures 950 based on information associated with the batteries 960, including the battery type, the structure in which the plurality of batteries is electrically connected, etc., and, thus, job changes (J/C) can be facilitated. Further description in this regard will be provided below in relation to FIG. 12.

The first additional probe and the second additional probe may be electrically connected to each other. For example, the first additional probe and the second additional probe may be electrically connected to each other by a connection cable.

The gas vent ports 940 may be disposed on a surface of the ceiling of the charging and discharging system and be configured to discharge gases generated inside the batteries 960 during a charging and discharging job. For example, the gas vent ports 940 can maintain stability or suppress an increase in the internal temperature of the batteries 960 by adjusting the internal pressures of the batteries 960 by discharging gases generated in the batteries 960.

In an embodiment, the probes 920 and 930 and the gas vent ports 940 may be disposed on the underside of the ceiling of the charging and discharging system so that their positions can be adjusted according to the information associated ith the batteries. A description of this configuration will be given below in relation to FIG. 12.

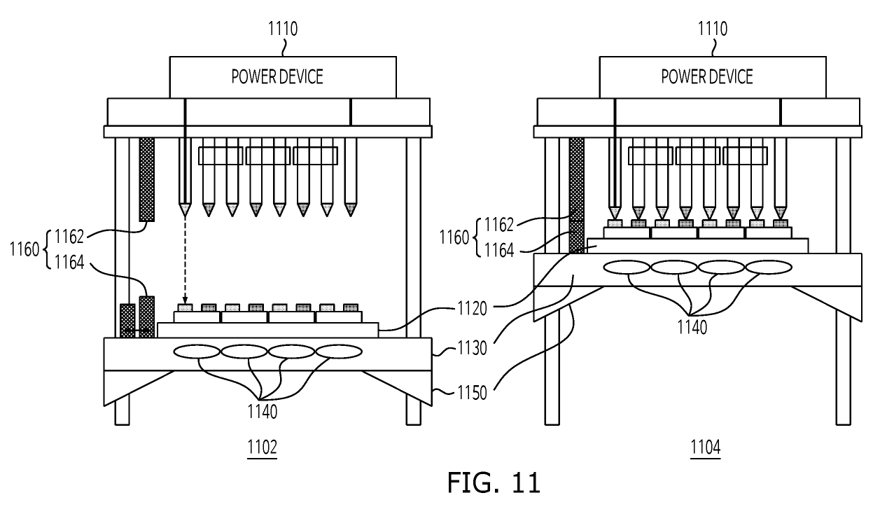

The tray 970 may be configured to house the batteries 960 to be charged and discharged and may correspond to the tray 120 of FIG. 2. The tray 970 housing the batteries 960 may be disposed on the tray support 978 at a predetermined height. Further, the tray 970 may be disposed on the upper surface of the tray lifting plate 972 by the tray alignment device 974, with the lifting device 976 being configured to lift the lifting plate 972. A description of this configuration will be given below in relation to FIG. 11.

The tray alignment device 974 may control the position of the tray 970 in the horizontal direction. The tray alignment device 974 may be disposed on the lifting plate 972.

The temperature adjustment devices 982 and 984 may correspond to the temperature adjustment unit 140 of FIG. 1. The temperature adjustment devices 982 and 984 may include power cooling devices 982 that adjust the temperature of the power device 910 and battery cooling devices 984 that adjust the temperature of the batteries 960. The battery cooling devices 984 may be disposed inside/below/above the lifting plate 972 and adjust the temperature of the tray 970 or batteries 960 disposed on the lifting plate 972. The power cooling devices 982 may be disposed below/above the power device 910 and adjust the temperature of the power device 910.

FIG. 9 shows how the tray 970 is raised together with the lifting plate 972 and the terminals of the electrodes come into contact with the probes. But the present disclosure is not limited to such an embodiment. For example, the probes may be lowered and come into contact with the terminals of the electrodes.

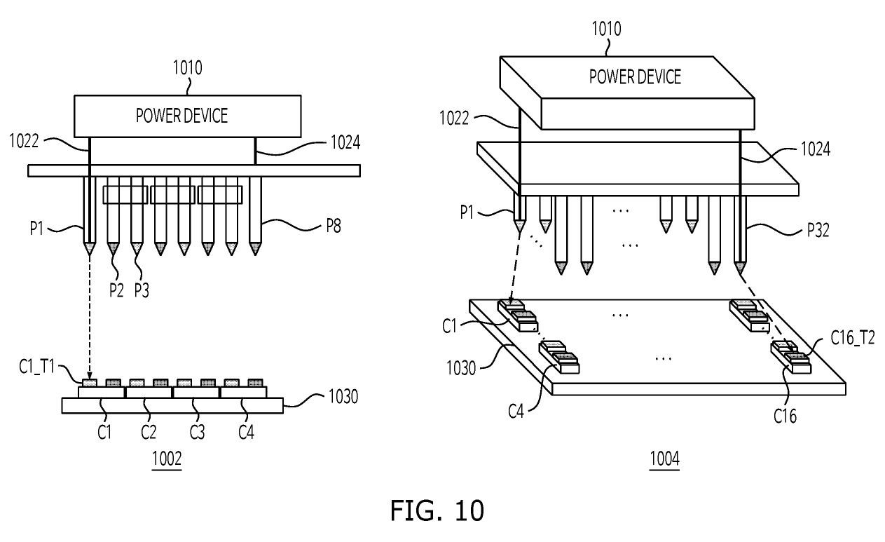

FIG. 10 shows the structure of a charging and discharging system according to an embodiment of the present disclosure. FIG. 10 shows a front view 1002 and a perspective view 1004 of the charging and discharging system. The charging and discharging system may include a power device 1010, power cables 1022 and 1024, a plurality of probes (e.g., P1, P8, P32) and a plurality of additional probes (e.g., P2, P3), a plurality of batteries (e.g., C1 to C16) to be charged and discharged, and a tray 1030 capable of housing the plurality of batteries.

FIG. 10 shows an example of a charging and discharging system including a total of 16 batteries C1 to C16, and a total of 32 probes including a plurality of probes (e.g., P1, P8, P32) and additional probes (e.g., P2, P3) corresponding to the electrode terminals of each battery. But the present disclosure is not limited to this example.

The positive terminal of the power device 1010 may be connected to a first probe P1 via a first power cable 1022. A part of the first power cable 1022 may be disposed inside the first probe P1 (e.g., inside the probe fixture). Further, the negative terminal of the power device 1010 may be connected to a thirty-second probe P32 via a second power cable 1024. A part of the second power cable 1024 may be disposed inside the second probe P2 (e.g., inside the probe fixture). Here, the first probe P1 may be electrically connected to the positive terminal C1_T1 of a first battery C1 of a first set of batteries C1 to C4 in a first battery group. Similarly, the thirty-second probe P32 may be electrically connected to the negative terminal C16_T2 of a sixteenth battery C16 of a fourth battery group.

A first additional probe P2 may be connected to the negative terminal of the first battery C1, and a second additional probe P3 may be connected to the positive terminal of a second battery C3. Further, the first additional probe P2 and the second additional probe P3 may be electrically connected to each other by a connection cable. Moreover, the first additional probe P2 and the second additional probe P3 may be physically coupled to each other by a connection structure.

FIG. 11 shows the structure of a charging and discharging system according to an embodiment of the present disclosure. IA first state 1102 may be before a lifting device 1150 raises a lifting plate 1130, and a second state 1104 may be in which the lifting device 1150 has raised the lifting plate 1130 to bring a plurality of probes and the electrode terminals of a plurality of batteries into contact.

In the first state 1102, a tray 1120 with batteries disposed on an upper surface thereof may be disposed on a tray support at a predetermined height. Then, a control unit may control the lifting device to cause the lifting plate 1130 to be raised to the predetermined height. Accordingly, the tray 1120 can be disposed on the lifting plate 1130. Then, the control unit may control a tray alignment device so that the position of the tray in the horizontal direction is aligned at the predetermined height. The control unit may then control the lifting device so that the probes contact the corresponding battery groups. With this control, the first probe and the second probe may contact the first battery group, and the third probe and the fourth probe may contact the second battery group.

The charging and discharging system may include a stopper 1160. The stopper 1160 can prevent the tray 1120 and the probes from colliding during a job change (J/C). The stopper 1160 may include a lower stopper 1164 disposed on the lifting plate 1130 and an upper stopper 1162 opposing the lower stopper 1164. Further, the lower stopper 1164 may include a plurality of lower stoppers. The lower stoppers 1164 may differ in their heights or widths, and the lower stoppers 1164 may differ in the materials from which they are formed.

The control unit may control the lifting device 1150 to raise the lifting plate 1130 until the upper stopper 1162 and the lower stopper 1164 come into contact. The control unit may select one of the lower stoppers 1164 based on at least one of information on the batteries, including the types, specifications, etc., of the batteries, and height information of the tray 1120 or position information of the probes. For example, the control unit may select one lower stopper 1164 based on information associated with the first set of batteries included in the first battery group, and the control unit may control the lifting device 1150 based thereon.

FIG. 12 is a diagram showing the configuration of a charging and discharging system according to one embodiment of the present disclosure. FIG. 12 shows an example of a structure in which a plurality of probes P1 and P8, a plurality of additional probes P2 to P7, and gas vent ports H1 to H4 are provided in the charging and discharging system.

The probes may include positive probes P1, P3, P5, and P7, and negative probes P2, P4, P6, and P8. Here, the positive probes P1, P3, P5, and P7 may be connected to the positive terminals of a first battery group. The negative probes P2, P4, P6, and P8 may be connected to the negative terminals of the first battery group.

The charging and discharging system may include a first driving unit M1 configured to move the positive probes P1, P3, P5, and P7 in a horizontal direction, and a third driving unit M3 configured to move the negative probes P2, P4, P6, and P8 in the horizontal direction. The charging and discharging system may further include a second driving unit M2 configured to move the gas vent ports H1 to H4 corresponding to the first battery group in the horizontal direction. The first driving unit M1, the second driving unit M2, and/or the third driving unit M3 may include a motor (e.g., a servo motor) and a ball screw.

The control unit may receive information associated with a first set of batteries included in the first battery group, and the control unit may control at least one of the first driving unit M1, the second driving unit M2, or the third driving unit M3 based on the information. The information associated with the first set of batteries may include at least one of specifications of the batteries, types of the batteries, and the structure in which the batteries is electrically connected.

A first additional probe P2, a second additional probe P3, a third additional probe P4, a fourth additional probe P5, a fifth additional probe P6, and a seventh additional probe P7 may each be physically coupled to each other by a connection structure 1254.

The connection structure 1254 can cause the distance between the fourth additional probe P4 and the fifth additional probe P5 to be greater than or equal to a predetermined minimum distance and less than or equal to a predetermined maximum distance. With this structure, job changes (J/C) can be performed easily based on the information associated with the batteries by adjusting the horizontal distance between combinations of the plurality of additional probes. Further, management of the additional probes can be facilitated by limiting the horizontal distance between combinations of the additional probes.

The connection structure 1254 may include a sliding rail. In particular, the connection structure 1254 may include a first rail 1254_1, a carriage (or sliding block) 1254_2, and a second rail 1254_3.

FIG. 13 is a diagram showing a control unit of a charging and discharging system according to an embodiment of the present disclosure. The battery information sensing unit 150 may sense information 1230 associated with batteries to be charged and discharged. Further, the battery information sensing unit 150 may transmit the sensed information 1230 to the control unit 160. The control unit 160 may control the charging and discharging system based on the information 1230 received from the information sensing unit 150. The information 1230 associated with the batteries to be charged and discharged may include battery type information 1312, electrical connection information 1314, and charging and discharging state information 1316. The battery type information 1312 may include information such as specifications and types of the batteries to be charged and discharged. The specifications or types of the batteries may include a rated charging voltage, a rated charging current, a rated charging power, a rated charging temperature, a distance between the positive and negative terminals, etc., of the batteries.

The control unit 160 may set the configuration or number of power devices based on the battery type information 1312. The electrical connection information 1314 may include information on the structure in which the plurality of batteries is electrically connected, etc. For example, the electrical connection information 1314 may include the number of batteries to be connected in series included in a battery group, the number of battery groups, etc.

The charging and discharging state information 1316 may include information on the charging or discharging state of each of the plurality of batteries. For example, the state information 1316 may indicate whether charging or discharging of each of the batteries is complete. Information on whether each of the batteries is defective may also be included.

The control unit 160 may change the electrical structure of the charging and discharging control board based on at least one of the battery type information 1312, the electrical connection information 1314, or the charging and discharging state information 1316. Specifically, the control unit 160 may control the bypass relays included in the charging and discharging control board based on at least one of the battery type information 1312, the electrical connection information 1314, or the charging and discharging state information 1316. For example, the control unit 160 can control the bypass relays connected to a battery group including a battery that has been determined to be defective, a battery group including a battery for which charging has been completed, etc., thereby releasing the series connection between the battery group and the power device.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure.

### DESCRIPTION OF SOME REFERENCE SYMBOLS

100: Charging and discharging system

110: Power supply unit

120: Tray

130: Charging and discharging control board

140: Temperature adjustment unit

150: Battery information sensing unit

160: Control unit

What is claimed is:

1. A charging and discharging system comprising:
a power device;
a tray configured to contain a first battery group including a first set of batteries connected in series and a second battery group including a second set of batteries connected in series; and
a charging and discharging control board electrically connected to the power device, the first battery group, and the second battery group,
wherein the charging and discharging control board comprises:
a first bypass relay providing a first path for making a series connection between the first battery group and the power device and a second path for releasing the series connection between the first battery group and the power device; and
a second bypass relay providing a third path for making a series connection between the second battery group and the power device and a fourth path for releasing the series connection between the second battery group and the power device.

2. The charging and discharging system as claimed in claim 1, further comprising a control unit configured to control the charging and discharging control board,
wherein the control unit is configured to stop a charging and discharging job for the first battery group by controlling the first bypass relay to provide the second path.

3. The charging and discharging system as claimed in claim 1, further comprising:
a first probe electrically connecting a first end of the first battery group and a first terminal of the first bypass relay;
a second probe electrically connecting a second end of the first battery group and a second terminal of the first bypass relay;
a third probe electrically connecting a first end of the second battery group and a first terminal of the second bypass relay; and
a fourth probe electrically connecting a second end of the second battery group and a second terminal of the second bypass relay,
wherein, when the first bypass relay provides the first path, the second terminal of the first bypass relay and a third terminal of the first bypass relay are electrically connected, and the third terminal of the first bypass relay is electrically connected to the third probe.

4. The charging and discharging system as claimed in claim 3, wherein, when the first bypass relay provides the second path, the first terminal of the first bypass relay and the third terminal of the first bypass relay are electrically connected.

5. The charging and discharging system as claimed in claim 3, further comprising a plurality of additional probes connecting the first set of batteries in the first battery group in series.

6. The charging and discharging system as claimed in claim 5, further comprising a connection structure fixing a first additional probe and a second additional probe of the additional probes,
wherein the first additional probe and the second additional probe are electrically connected to each other.

7. The charging and discharging system as claimed in claim 6, wherein the connection structure is configured to make a distance between the first additional probe and the second additional probe to be greater than or equal to a predetermined minimum distance and less than or equal to a predetermined maximum distance.

8. The charging and discharging system as claimed in claim 6, wherein the connection structure is a sliding rail.

9. The charging and discharging system as claimed in claim 6,
wherein the first probe is configured to be connected to a positive terminal of a first battery,
wherein the first additional probe is configured to be connected to a negative terminal of the first battery,
wherein the second additional probe is configured to be connected to a positive terminal of a second battery, and
wherein the first additional probe and the second additional probe are configured to connect the first battery and the second battery in series.

10. The charging and discharging system as claimed in claim 1, further comprising:
a plurality of positive probes configured to be connected to positive terminals of the first battery group;
a plurality of negative probes configured to be connected to negative terminals of the first battery group;
a first driving unit configured to move the plurality of positive probes in a horizontal direction; and
a second driving unit configured to move the plurality of negative probes in a horizontal direction.

11. The charging and discharging system as claimed in claim 10, further comprising:
a control unit configured to receive information associated with the first set of batteries included in the first battery group and configured to control at least one of the first driving unit or the second driving unit based on the received information.

12. The charging and discharging system as claimed in claim 11, wherein the information associated with the first set of batteries comprises information on a distance between a positive terminal and a negative terminal of a battery.

13. The charging and discharging system as claimed in claim 3, wherein the charging and discharging control board further comprises a third bypass relay providing a fifth path for making a series connection between a third battery group and the power device and a sixth path for releasing the series connection between the third battery group and the power device,
wherein the charging and discharging system further comprises:
a fifth probe configured to electrically connect a first end of the third battery group and a first terminal of the third bypass relay; and
a sixth probe configured to electrically connect a second end of the third battery group and a second terminal of the third bypass relay, and
wherein a positive terminal of the power device is electrically connected to the first probe via a first power cable, and a negative terminal of the power device is connected to a third terminal of the third bypass relay via a second power cable.

14. The charging and discharging system as claimed in claim 3, further comprising:
a lifting plate, with the tray being disposed on an upper surface of the lifting plate;
a lifting device configured to lift the lifting plate; and
a control unit configured to control the lifting device,
wherein the charging and discharging system is configured such that when the tray is raised by the lifting device (i) the first probe and the second probe contact the first battery group and (ii) the third probe and the fourth probe contact the second battery group.

15. The charging and discharging system as claimed in claim 14, further comprising:
a lower stopper disposed on the lifting plate; and
an upper stopper opposing the lower stopper,
wherein the control unit is configured to control the lifting device to raise the lifting plate until the upper stopper and the lower stopper come into contact.

16. The charging and discharging system as claimed in claim 15, wherein the control unit is configured to select the lower stopper is out of a plurality of lower stoppers based on information associated with the first set of batteries included in the first battery group.

17. The charging and discharging system as claimed in claim 14, further comprising:
a tray alignment device configured to control a position of the tray in a horizontal direction,
wherein the control unit is configured to control the lifting device so that the lifting plate is raised to a predetermined height, and
wherein the control unit is configured to control the tray alignment device so that the position of the tray in the horizontal direction is aligned at the predetermined height.

18. The charging and discharging system as claimed in claim 1, further comprising:
a power cooling device configured to cool the power device; and
a battery cooling device configured to cool the first set of batteries and the second set of batteries.

19. A charging and discharging system comprising:
a power device;
a bypass relay configured to provide a first path that makes a series connection between a battery group and the power device and a second path that releases the series connection between the battery group and the power device;
a first probe configured to electrically connect a first end of the battery group and a first terminal of the bypass relay;
a second probe configured to electrically connect a second end of the battery group and a second terminal of the bypass relay; and
a plurality of additional probes configured to connect batteries in the battery group in series,
wherein, when the bypass relay provides the first path, the second terminal of the bypass relay and a third terminal of the bypass relay are electrically connected, and
wherein, when the bypass relay provides the second path, the first terminal of the bypass relay and the third terminal of the bypass relay are electrically connected.

20. The charging and discharging system as claimed in claim 19, wherein a positive terminal of the power device is electrically connected to the first probe via a first power cable, and
wherein the third terminal of the bypass relay is electrically connected to a subsequent probe that is configured to be associated with a subsequent battery group.
